(19) United States
(12) Patent Application Publication
(10) Pub. No.: US 2007/0114581 A1
(43) Pub. Date: May 24, 2007

(54) Transistor of semiconductor device and method for manufacturing the same

(75) Inventor: Jeong Ho Park, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/599,646

(22) Filed: Nov. 14, 2006

(30) Foreign Application Priority Data
Nov. 18, 2005 (KR) 10-2005-0110785

(51) Int. Cl. H01L 29/76

(52) U.S. Cl. 257/288

(57) ABSTRACT

A transistor of a semiconductor device capable of improving the device reliability, and a method for manufacturing the same are provided. The transistor includes an active portion having a first height from a semiconductor substrate surface and having a line-shaped cross-section; a device isolation layer in which a round portion at a second height lower than the first height from the semiconductor substrate surface; a gate insulating layer on the active portion; a gate electrode on the gate insulating layer intersecting the active portion; and source/drain terminals in the active region on opposite sides of the gate electrode.

### BACKGROUND OF THE INVENTION

1. Field of the Invention

The present invention relates to a transistor of a semiconductor device and a method for manufacturing the same, and more particularly, to a transistor capable of improving the reliability of the device, and a method for manufacturing the same.

2. Description of the Related Art

In general, as the integration degree of a semiconductor device increases, there is a demand for transistors smaller in size. However, there is a limitation to the shallowness of a junction depth of a source/drain terminal.

This is the reason why a short channel effect occurs. Here, as a length of a channel is reduced from a long channel of a related art to a short channel equal to or less than 0.5 μm, a source/drain depletion region penetrates into a channel to reduce a length of a valid channel and a threshold voltage. In the event, the short channel effect indicating a function of a gate control in a MOS transistor occurs.

So as to suppress such a short channel effect, a thickness of a gate insulating layer should be reduced. Further, the channel between the source and drain terminals, a maximum width of a depletion region under a gate, as well as a concentration of impurity ions in a semiconductor substrate should be reduced.

However, first of all, it is important to form a shallow junction. To do this, there have continuously been attempts to embody a shallow junction by a subsequent thermal treatment processes using ion implantation equipment in a manufacturing process of a semiconductor device.

Further, a MOS transistor may typically include a light doped drain (referred to as ‘LDD’ hereinafter) structure.

On the other hand, a MOS transistor mainly used in a semiconductor memory device such as DRAM typically is a planar type transistor, in which a gate insulating layer is formed at a surface of a silicon substrate, and a conductive layer pattern is formed on the gate insulating layer.

However, as semiconductor devices are highly integrated, a line width of a gate pattern, and a length and a width of a channel are reduced, undesirable effects such as a short channel effect or a shallow channel effect may increase in the operation of the transistor.

Further, a drive current in the MOS transistor flows through a substrate channel formed under a gate electrode in each cell. When a size of a device is reduced according to higher integration levels of the semiconductor device, the drive current flows through a limited depth and width, which is adjacent to a gate electrode. Accordingly, an amount of the drive current may be limited, thereby limiting operation characteristics of the transistor.

In order to solve a short channel effect and a drive current limit problem in the MOS transistor, a pin type MOS transistor has been suggested, which increases a drive current by increasing a contact area of a substrate and a gate electrode in a shallow junction structure.

Hereinafter, a transistor of a semiconductor device according to the related art will be explained with reference to accompanying drawings.

FIG. 1 is a perspective view showing a pin type MOS transistor according to the related art. FIG. 2 is a cross-sectional view of the pin type MOS transistor taken along line I-I of FIG. 1.

As shown in FIGS. 1 and 2, the pin type MOS transistor according to the related art includes a device isolation layer 101, an active portion 105, a gate electrode 106, a gate insulating layer 130, and source/drain terminals (not shown). The device isolation layer 101 is formed in a device isolation region of the semiconductor device 100. The active portion 105 protrudes upwards from an upper side of the device isolation layer 101. The active portion 105 has a line shape upon viewing the active portion in a layout or a cross-section. The gate electrode 106 is arranged perpendicular to the active portion 105. The gate insulating layer 130 insulates the active portion 105 from the gate electrode 106. The source/drain terminals are formed in the active portion 105 at opposite sides of the gate electrode 106.

Here, the gate electrode 106 passes over and encloses two side portions of a protruded active portion 105 and an upper surface connected thereto. Accordingly, the pin type MOS transistor has a gate length greater than that of a general (planar) MOS transistor by about two times the protruded height of the active portion 105, so that an amount of a drive current may be increased.

However, a transistor according to the related art has following problems.

In the MOS transistor shown in FIG. 5, because the upper surface and sides of the protruded active portion 105 are substantially arranged perpendicular to each other, an edge part A of the active portion 105 makes a right angle. This may cause damage to the gate insulating layer 101 in the edge part A of the active portion 105.

More particularly, an electric field may be concentrated in a part corresponding to the edge A of the active portion 105 in the gate insulating layer 101.

### SUMMARY OF THE INVENTION

Accordingly, the present invention is directed to a transistor of a semiconductor device and a method for manufacturing the same that substantially obviates one or more problems due to limitations and disadvantages of the related art.

An object of the present invention is to provide a transistor that improves device reliability by preventing or reducing a likelihood of damage to a gate insulation layer.

Another object of the present invention is to provide a method for manufacturing the transistor.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, there is provided transistor comprising: an active portion having a first height from a surface of a semiconductor substrate, and having a line-shaped cross-section; a device isolation layer having a round portion at a second height lower than the first height; a gate insulating layer on the active portion; a gate electrode on the gate insulating layer, intersecting the active portion; and source/drain terminals in the active region on opposite sides of the gate electrode.

In another aspect of the present invention, there is provided a method for manufacturing a transistor comprising: forming first and second insulating layer patterns defining an active region of a semiconductor substrate; selectively removing portions of the substrate in device isolation regions using the first and second insulating layer patterns as a mask to form a trench and an active portion having a first height; forming a device isolation layer having a second height lower than the first height in the trench, the device isolation layer including a round portion at a sidewall of the active portion; forming a gate electrode structure intersecting the active region; and forming source/drain terminals at opposite sides of the gate electrode structure in the active portion.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a perspective view showing a pin type MOS transistor according to the related art;

FIG. 2 is a cross-sectional view of the pin type MOS transistor taken along line I-I of FIG. 1;

FIG. 3 is a perspective view showing a pin type MOS transistor according to an embodiment of the present invention;

FIG. 4 is a cross-sectional view of the pin type MOS transistor taken along line II-II of FIG. 3;

FIG. 5 is a cross-sectional view of the pin type MOS transistor taken along line III-III of FIG. 3; and

FIGS. 6A through 6J are cross-sectional views of a pin type MOS transistor for describing a method for manufacturing a transistor according to an embodiment of the present invention.

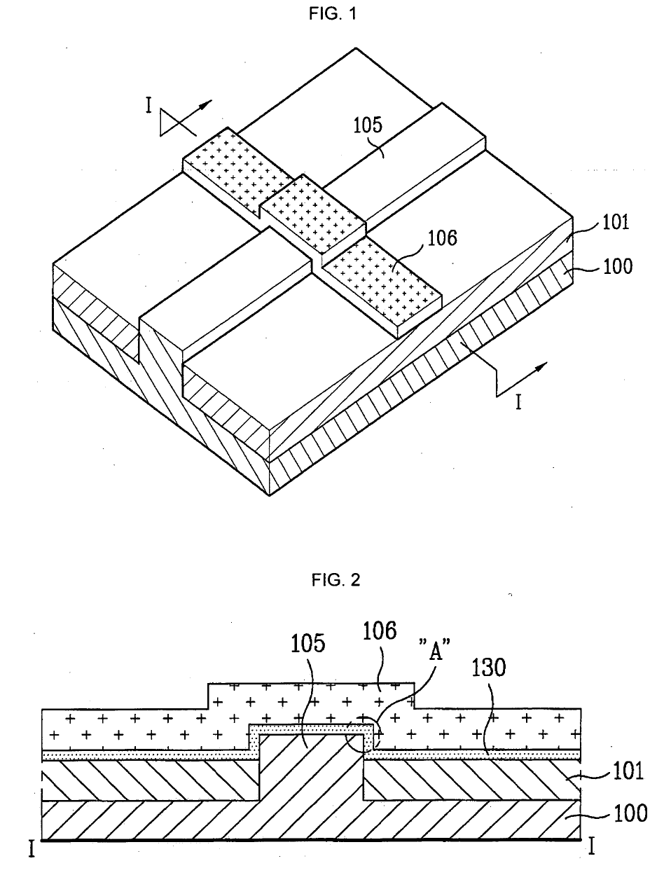

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a transistor of a semiconductor device and a method for manufacturing the same according to an embodiment of the present invention will be described with reference to the accompanying drawings.

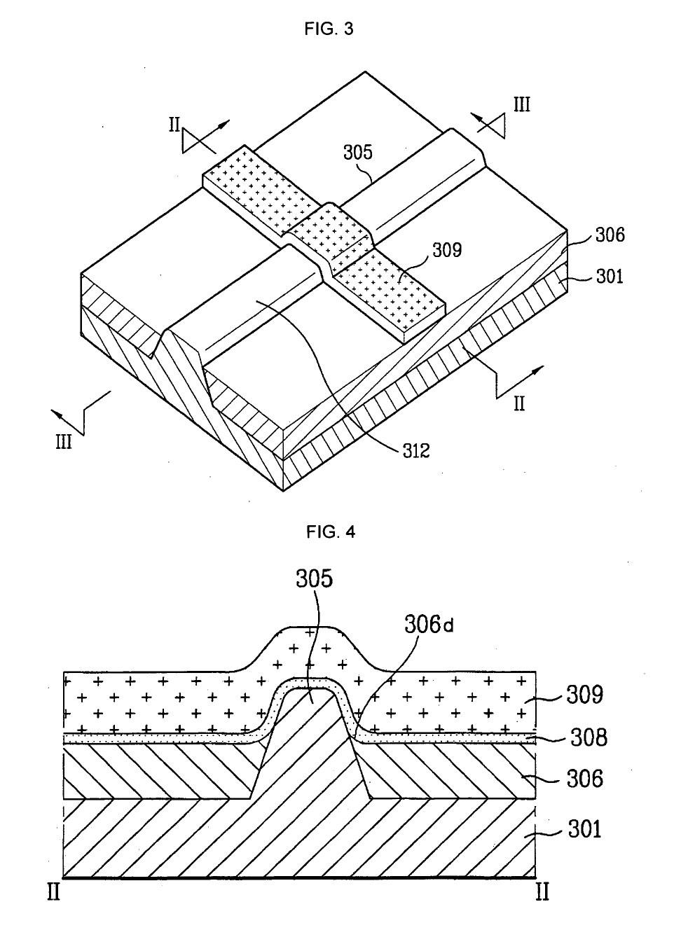

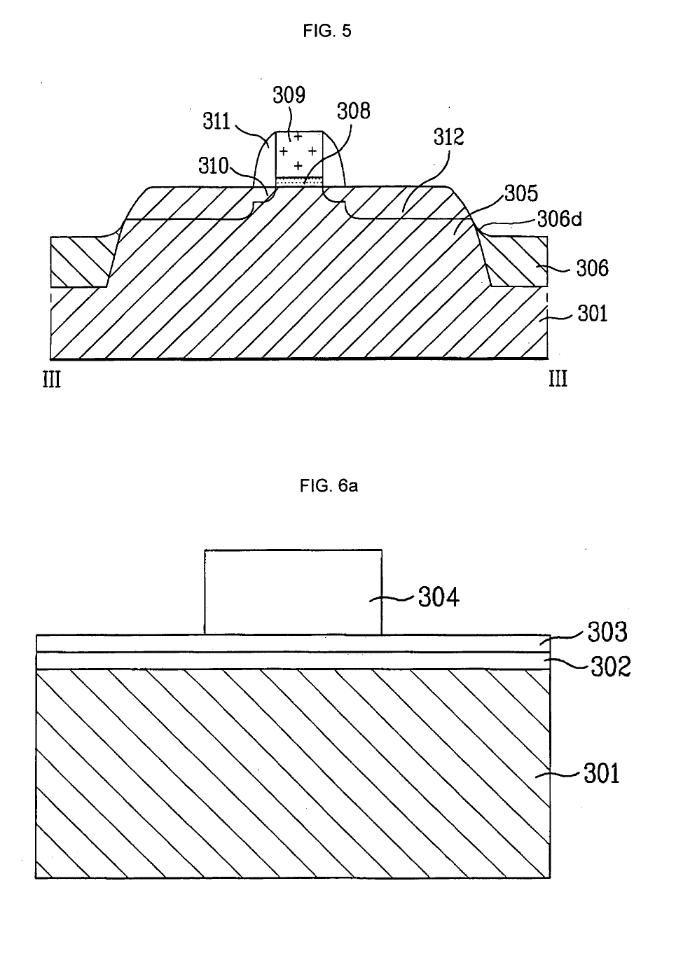

FIG. 3 is a perspective view showing a pin type MOS transistor according to an embodiment of the present invention. FIG. 4 is a cross-sectional view of the pin type MOS transistor taken along line II-II of FIG. 3. FIG. 5 is a cross-sectional view of the pin type MOS transistor taken along line III-III of FIG. 3.

As shown in FIGS. 3 through 5, the pin type MOS transistor according to the embodiment of the present invention includes a device isolation layer 306 with a round portion 306d, an active portion 305, a gate insulating layer 308, a gate electrode 309, a sidewall spacer 311, an LDD 310, and source/drain terminals 312.

The active portion 305 protrudes to a first height from a surface of the semiconductor substrate 301. The active portion 305 may have a long line shape upon viewing it on a plane (e.g., by viewing a two-dimensional cross-section, such as the view of FIG. 5, or as viewed in a top-down, layout view).

On the other hand, active portion 305 may have a trapezoid shape in a cross-sectional view. More particularly, the active portion 305 has a shape in which a sectional area or dimension (e.g., a width) becomes gradually smaller as it goes from the semiconductor substrate 301 toward the uppermost surface of the active portion 305. Accordingly, the active portion 305 may form an obtuse angle (e.g., from 75° to 88°, from 80° to 85°, or any range of values therein) with respect to the semiconductor substrate 301.

On the other hand, an upper edge of the active portion 305 may be rounded. Rounding the upper edge of the active portion 305 may prevent or reduce an electric field from being concentrated in a corresponding portion of gate insulating layer 308 as will be described later.

Device isolation layers 306 are arranged at or in device isolation regions, which are formed at both (opposite, or surrounding all) sides of the active portion 305. In embodiments of the present invention, each of the device isolation layers 306 has a second height lower than the first height of the active layer 305. A rounded portion 306d is formed where the device isolation layer 306 contacts a sloped side of the active portion 305. The device isolation layer 306a and/or the round portion 306d functions to prevent or reduce a contact part between the device isolation layer 306 and the active portion 305 from being excessively etched during a subsequent process.

The gate insulating layer 308 covers at least the part of the active portion 305 under the gate electrode 309. Optionally, the gate insulating layer 308 covers the device isolation layer 306, at least under the extended portions of the gate electrode 309. In these embodiments, a sloped side of the active portion 305 and a round portion of the device isolation layer 306 prevent or reduce undesirable concentration(s) of an electric in the gate insulating layer 308, thereby preventing or reducing the likelihood of dielectric breakdown of gate insulating layer 308, and suppressing damage to the gate insulating layer 308.

In some embodiments, the gate insulating layer 308 may comprise a hafnium silicon oxynitride (Hf—Si—O—N) or a hafnium silicon oxide (Hf—Si—O).

The gate electrode 309 is arranged on the gate insulating layer 308 substantially perpendicular to the active portion 305. In this embodiment, the gate electrode 309 may have a line shape (e.g., a line-shaped cross-section, or a general line shape when a user views a layout thereof).

A sidewall spacer 309 is arranged at both sides of the gate electrode 308. The sidewall spacer 309 is used to protect the LDD 310 in the active portion 305 after formation thereof. The LDD 310 is formed at a lower portion of the sidewall spacer 309. The LDD 310 arranged at the lower portion of the sidewall spacer 309 is combined with source/drain terminals 312 of the active portion 305.

In various embodiments of the present invention, the active portion 305 protruding from the semiconductor substrate 301 may have a trapezoidal shape, optionally with rounded upper corners, and the device isolation layer 306 may have a round portion 306d where it contacts with a sloped sidewall of the active portion 305, thereby preventing or reducing the likelihood of damage to the gate insulating layer 308.

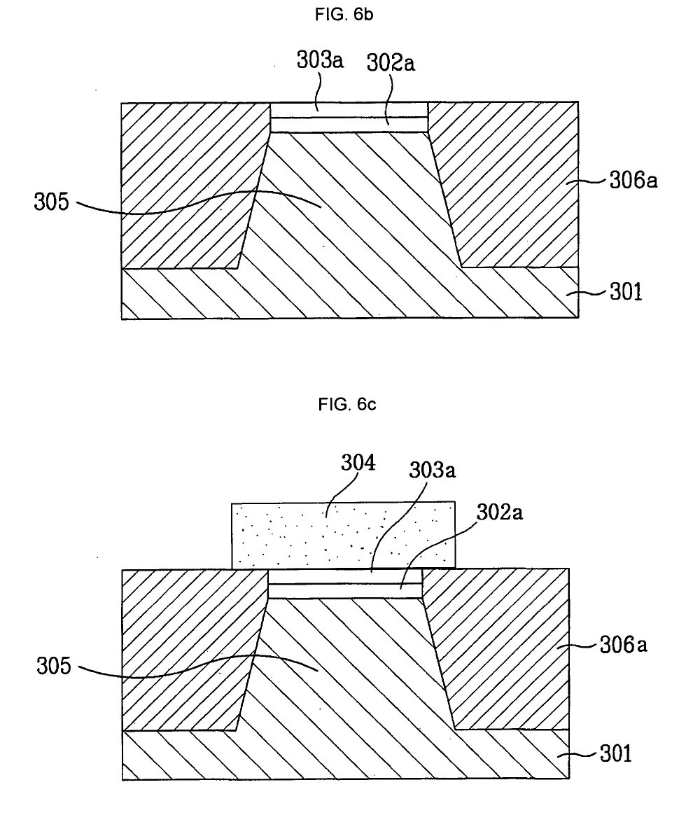

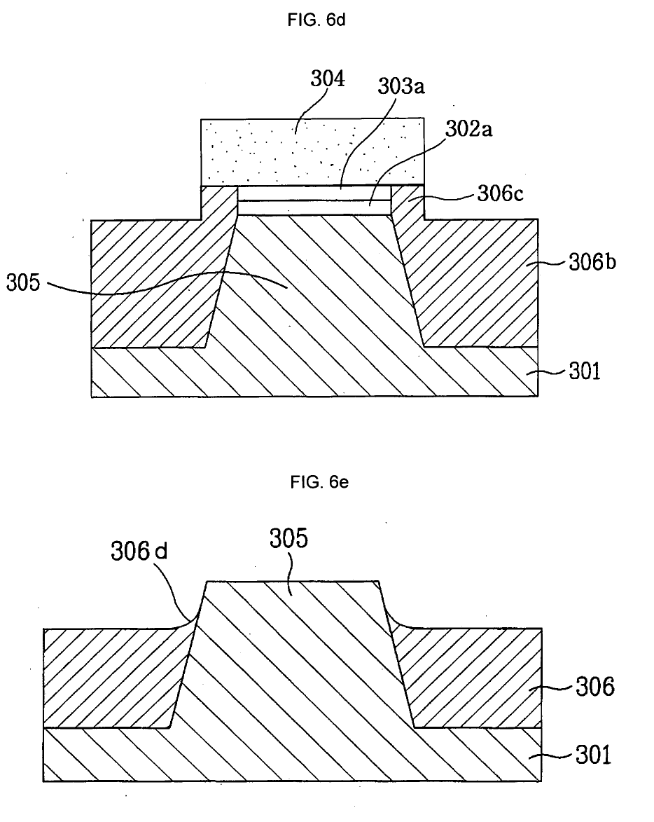

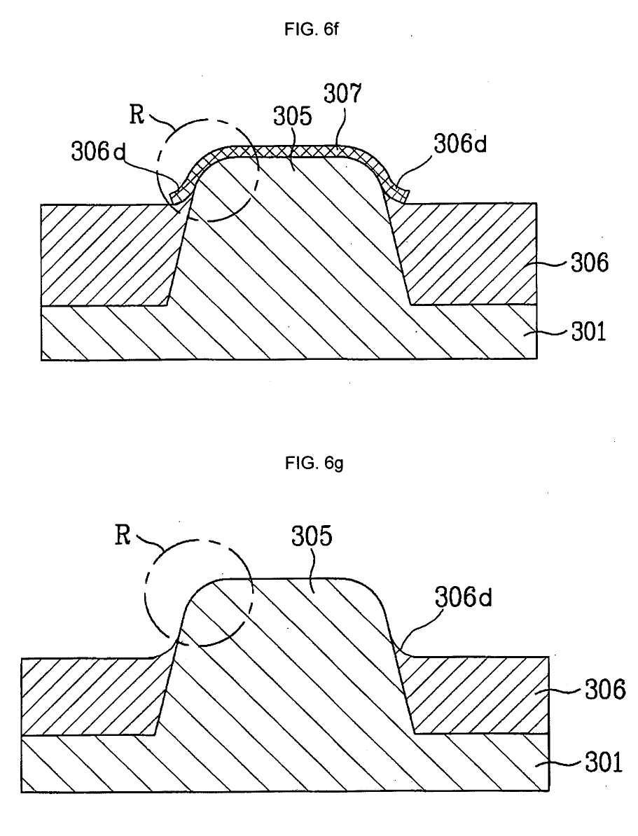

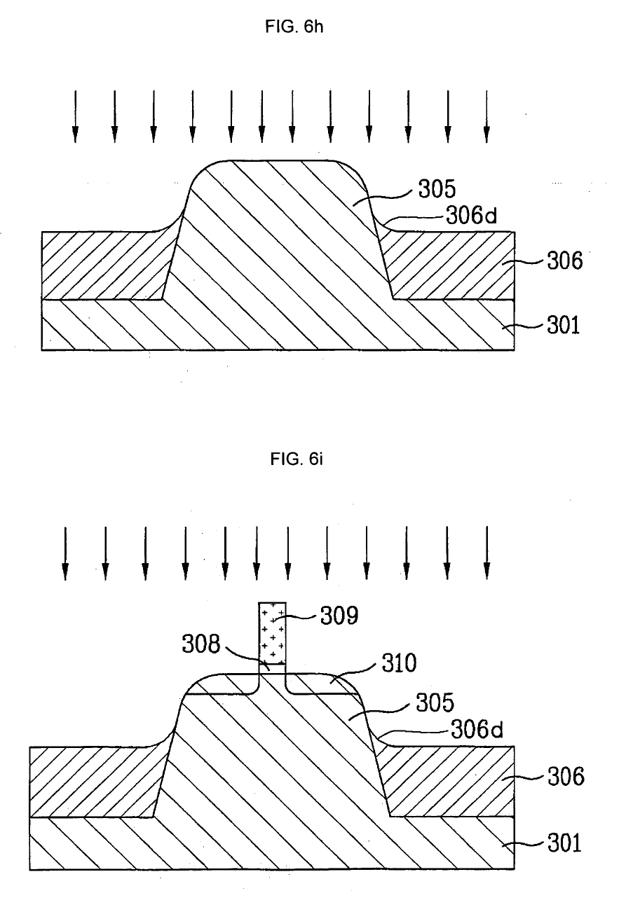

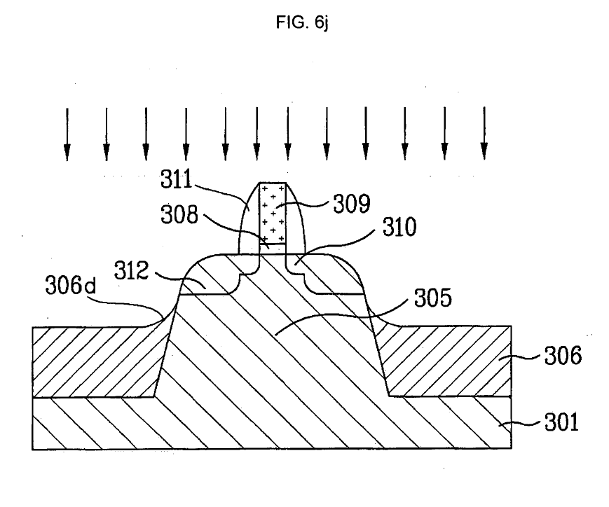

FIGS. 6A through 6J are cross-sectional views of a pin type MOS transistor for describing a method for manufacturing a transistor according to an embodiment of the present invention.

Firstly, as shown in FIG. 6A, a first insulating layer 302 and a second insulating layer 303 are sequentially formed on the semiconductor substrate 301.

The first insulating layer 302 may include an oxide layer (e.g., comprising silicon dioxide), which may have a thickness ranging from 20 to 100 Å and be formed by conventional wet or dry thermal oxidation (e.g., of silicon) or conventional chemical vapor deposition (CVD) (e.g., from precursor gases such as a silane or TEOS and dioxygen) with optional annealing for densification. Further, the second insulating layer 303 can include a nitride layer, which has a thickness ranging from 500 to 1,500 Å and be formed by conventional thermal nitridation (e.g., of silicon dioxide) or conventional chemical vapor deposition (e.g., from precursor gases such as a silane and dinitrogen or ammonia).

Although this embodiment of the present invention has been described in that the first insulating layer 302 and the second insulating layer 303 are sequentially formed, the present invention is not limited thereto. That is, a single insulating layer (e.g., comprising silicon nitride or a silicon oxynitride) can be formed for a mask.

After a photo resist layer is coated on the second insulating layer 303, the photo resist layer is patterned by a conventional photolithography process including exposure and developing processes to form a first photo resist pattern 304.

The first photo resist pattern 304 defines an active region where an active portion 305 to be described later will be formed. The removed part of the first photo resist pattern 304 defines a device isolation region, where the device isolation layer 306 to be explained below will be formed.

As shown in FIG. 6B, the first insulating layer 302 and the second insulating layer 303 are patterned using the first photo resist pattern 304 as an etch mask to form a first insulating layer pattern 302a and a second insulating layer pattern 303a.

After a formation of the first insulating layer pattern 302a and the second insulating layer pattern 303a, the first photo resist pattern 304 is removed from the semiconductor substrate 301.

The semiconductor substrate 301 is patterned (e.g., by dry etching using a conventional etch chemistry for etching silicon, which may comprise one or more fluorocarbon, hydrofluorocarbon, halogen and/or hydrogen halide etchants that are typically in the gas phase at ambient temperatures), using the first insulating layer pattern 302a and the second insulating layer pattern 303a to form a trench having a predetermined depth at a device isolation region of the semiconductor substrate 301, and to form an active portion 305 at an active region. In this embodiment, the active portion 305 has a line shape as described herein (e.g., in a planar or cross-sectional view).

In this embodiment of the present invention, after the first photo resist pattern 304 has been removed, the semiconductor substrate 301 is patterned using the first insulating layer pattern 302a and the second insulating layer pattern 303a as an etch mask to form the trench. However, the trench can also be formed using the photo resist pattern 304 as the etch mask without prior removal of the photo resist pattern 304.

After the trench and the active portion 305 have been formed, a third insulating layer is formed on/over an entire surface of the semiconductor substrate 301 (e.g., by a blanket deposition technique such as CVD). Generally, the third insulating layer comprises a silicon oxide (e.g., as described herein). However, prior to blanket deposition of the third insulating layer, a thin liner oxide (not shown) may be formed along the surface of the trench by wet or dry thermal oxidation.

Next, the third insulating layer is polished or planarized by a chemical mechanical polishing process using an upper surface of the second insulating layer pattern 303a as an end point to form a first preliminary device isolation layer 306a inside the trench.

As shown in FIG. 6C, a photo resist layer is again formed at an upper surface of the first preliminary device isolation layer 306a. Then, the photo resist layer is patterned using a photolithography process to form a second photo resist pattern 304′, which covers a part of the first preliminary device isolation layer 306a as well as first and second insulating layer patterns 302a and 303a.

As shown in FIG. 6D, parts of the first preliminary device isolation layer 306a are dry-etched using the second photo resist pattern 304 as an etch mask to form a second preliminary device isolation layer 306b having a stepped portion 306c inside the trench (or over a sidewall boundary portion of the trench, if the trench is considered to be defined by a region of the semiconductor substrate removed during the etching step described above with regard to FIG. 6B).

As shown in FIG. 6E, after the second preliminary device isolation layer 306b having the stepped portion 306c has been formed, the second photo resist pattern 304 is removed.

Subsequently, the first insulating layer pattern 302a and the second insulating layer pattern 303a are removed from the active portion 305 by one or more wet etch processes. When the first insulating layer pattern 302a and the second insulating layer pattern 303a are removed from the active portion 305, the second preliminary device isolation layer 306b having a stepped portion 306c is also etched to form a device isolation layer 306 inside the trench.

As the second preliminary device isolation layer 306b having the stepped portion 306c is etched (e.g., using dilute aqueous hydrofluoric acid, where the ratio by volume of deionized water to concentrated aqueous HF may be from about 1:1 to about 10:1), a round portion 306d is formed at a part of the device isolation layer 306 corresponding to the stepped portion 306c. The round portion 306c prevents an excessive etch in a contact part between the active portion 305 and the device isolation layers 306.

In the embodiment of the present invention, the second insulating layer pattern 303a is removed using an aqueous phosphoric acid or phosphate solution. When (or after) the first insulation layer pattern 302a is removed, the second preliminary isolation layer 306b may be removed to a predetermined thickness.

In addition, after the second insulating layer pattern 303a and the first insulating layer pattern 302a have been removed (or after the first insulating layer pattern 302a is removed and during wet etching of the second insulating layer pattern 303a), the second preliminary device isolation layer 306b may be removed to a predetermined thickness from the surface (or for a predetermined period of time) through a separate etch, namely, an etch back process to protrude an active region 305.

As shown in FIG. 6F, an oxidation process (e.g., conventional wet or dry thermal oxidation) is performed on the semiconductor substrate 301 or the active portion 305 to form a fourth insulating layer 307. Alternatively, fourth insulating layer 307 may be formed by CVD (e.g., of silicon oxide) and optional annealing, as described above for the first insulating layer 302. The fourth insulating layer 307 on the upper surface of the protruded active portion 305 may be a sacrificial layer.

Here, reference symbol R represents that an edge part of the active portion 305 is rounded by an oxidizing process of the semiconductor substrate 301. The fourth insulating layer 307 preferably has a thickness ranging from approximately 50 Å to approximately 300 Å.

As shown in FIG. 6G, after forming rounded corners R on the active portion 305, the fourth insulating layer 307 may be removed using a wet etch process, as described above for silicon oxide.

As shown in FIG. 6H, impurity ions for forming a well and/or adjusting a threshold voltage are implanted in an entire surface of the semiconductor substrate 301 using a conventional ion implantation method. Alternatively, one or both ion implantations may be performed prior to removing the fourth insulating layer 307, to reduce possible damage to the active portion 305 during the ion implantation process.

As shown in FIG. 6I, a gate insulating layer 308 is formed at an entire surface of the semiconductor substrate 301. The gate insulating layer 308 may be formed using a Chemical Vapor Deposition (CVD), a Physical Vapor Deposition (PVD), or an Atomic Layer Deposition (ALD) method. Further, the gate insulating layer 308 may comprise a hafnium silicon oxynitride (Hf—Si—O—N) or a hafnium silicon oxide (Hf—Si—O).

After a formation of the gate insulating layer 308, a conductive layer for a gate electrode is formed on the gate insulating layer 308. The conductive layer may comprise TiN, Ti/TiN, WₓN_{y}, or polysilicon.

Thereafter, the conductive layer and the gate insulating layer 308 are patterned and/or selectively removed through a photolithography process to form a gate electrode 309 at an upper surface of the protruded active portion 305. The gate electrode 309 may cross over, or intersect the active portion 305 at substantially a right angle.

Next, a low density of n- or p-type impurities are implanted in an entire surface of the semiconductor substrate 301 using the gate electrode 309 as an ion implantation mask to from a lightly doped drain (LDD) 310 at a surface of the active portion 305 of opposite sides of the gate electrode 309.

As shown in FIG. 6J, after a fifth insulating layer (comprising an oxide layer, a nitride layer, or a multi-layered combination thereof such as an oxide-nitride bilayer or an oxide-nitride-oxide trilayer) has been formed on the entire surface of the semiconductor substrate 301, an etch back process is performed to form sidewall spacers 311 at both sides of the gate electrode 309. Here, the fifth insulating layer can be formed by blanket deposition of a nitride layer or an oxide layer then a nitride layer by, e.g., CVD.

Thereafter, a high density of n- or p-type impurities are implanted in the entire surface of the semiconductor substrate 301 using the gate electrode 309 and the sidewall spacers 311 as an ion implantation mask to from source/drain terminals 312 (combined or in electrical contact with LDD 310) in the active portion 305.

It will be apparent to those skilled in the art that various modifications and variations can be made in the present invention. Thus, it is intended that the present invention covers the modifications and variations of this invention provided they come within the scope of the appended claims and their equivalents.

As is seen from the forgoing description, in the transistor of a semiconductor device and a method for manufacturing the same, because edge parts of a protruded active region are rounded, dielectric breakdown and/or a disconnection of the gate insulating layer along the edge parts may be prevented to enhance the reliability of a device.

In addition, according to the present invention, since a rounded portion is formed at an interface of an active portion and a device isolation layer along the sidewall of the active portion, it may prevent the active portion and a device isolation layer part contacting with the active portion from being damaged.

What is claimed is:

1. A transistor comprising:
an active portion having a first height from a surface of a semiconductor substrate, and having a line-shaped cross-section;
a device isolation layer having a round portion at a second height lower than the first height from the semiconductor substrate surface;
a gate insulating layer on the active portion;
a gate electrode on the gate insulating layer intersecting the active portion; and
source/drain terminals in the active region on opposite sides of the gate electrode.

2. The transistor according to claim 1, wherein the gate insulating layer comprises a hafnium silicon oxynitride layer or a hafnium silicon oxide layer.

3. The transistor according to claim 1, wherein a sidewall spacer is arranged at a sidewall of the gate electrode.

4. The transistor according to claim 3, wherein the active portion corresponding to a lower portion of the sidewall spacer has a light doped drain structure.

5. The transistor according to claim 1, wherein an active round portion is formed at an edge of the active.

6. A method for manufacturing a transistor comprising:
forming first and second insulating layer patterns defining an active region of a semiconductor substrate;
selectively removing portions of the semiconductor substrate using the first and second insulating layer patterns as a mask to form a trench and an active portion having a first height;
forming a device isolation layer having a second height lower than the first height in the trench, the device isolation layer including a round portion at a sidewall of the active portion;
forming a gate electrode structure to intersect the active region; and
forming source/drain terminals at opposite sides of the gate electrode structure in the active portion.

7. The method according to claim 6, wherein forming the first and second insulating layer patterns includes:
sequentially forming a first insulating layer and a second insulating layer on the semiconductor substrate; and
patterning the first and second insulating layers.

8. The method according to claim 7, wherein the first insulating layer has a thickness ranging from 20 to 100 Å, and the second insulating layer has a thickness ranging from 500 to 1,500 Å.

9. The method according to claim 6, wherein forming the device isolation layer includes:
forming a first preliminary device isolation layer inside the trench, the first preliminary device isolation layer having an upper surface coplanar with the second insulating layer pattern;
patterning the first preliminary device isolation layer using a photo resist pattern larger than the first and second insulating layer patterns to form a second preliminary device isolation layer having a stepped portion at a sidewall part of the active portion; and
etching back the first and second insulating layer patterns and the second preliminary device isolation layer.

10. The method according to claim 6, further comprising oxidizing a surface of the active portion to form a sacrificial layer prior to the formation of the gate insulating layer.

11. The method according to claim 10, wherein the sacrificial layer has a thickness ranging from 50 to 300 Å.

12. The method according to claim 6, further comprising implanting impurity ions to form a well and implanting impurity ions to adjust a threshold voltage of the transistor after forming the active portion.

13. The method according to claim 6, further comprising forming sidewall spacers at opposite sides of the gate electrode.

14. The method according to claim 6, wherein the gate insulating layer comprises a hafnium silicon oxynitride layer or a hafnium silicon oxide layer.

15. The method according to claim 6, wherein the gate electrode comprises a member selected from the group consisting of TiN, Ti/TiN, WₓN_{y}, and polysilicon.

16. The method according to claim 6, wherein removing the second insulating layer pattern comprises wet etching using an aqueous phosphoric acid or phosphate solution.
